(19) United States
(12) Patent Application Publication
(10) Pub. No.: US 2019/0341280 A1
(43) Pub. Date: Nov. 7, 2019

(54) WAFFER PEDESTAL WITH HEATING MECHANISM AND REACTION CHAMBER INCLUDING THE SAME

(71) Applicant: PIOTECH CO., LTD., SHENYANG (CN)

(72) Inventors: JUNICHI ARAMI, SHENYANG (CN); REN ZHOU, SHENYANG (CN)

(21) Appl. No.: 16/400,323

(22) Filed: May 1, 2019

(30) Foreign Application Priority Data
May 3, 2018 (CN) 201810413913.4

(51) Int. Cl. H01L 21/67; H01L 21/687

(52) U.S. Cl. CPC H01L 21/67103; H01L 21/68785

(57) ABSTRACT

The present invention discloses a wafer pedestal including a plate, a heating assembly and a heat insulation assembly embedded in the plate at a radial position that divides the plate into a first heating zone and a second heating zone.

### CROSS-REFERENCE TO RELATED APPLICATIONS

This non-provisional application claims priority under 35 U.S.C. § 119(a) on Patent Application No(s). 201810413913.4 filed in China on May 3, 2018, the entire contents of which are hereby incorporated by reference.

### BACKGROUND

### Technical Field

The present invention relates to a wafer pedestal of a semiconductor processing chamber, especially to a pedestal provided with multiple heating zones and a reaction chamber including the same.

### Description of Related Art

Among the semiconductor processing equipment, a reaction chamber is a processing chamber includes a pedestal used for supporting a wafer to perform various processes, such as etching process. During some processes involving gas reaction, there is a high demand to maintain a proper wafer temperature. Based on the demand, the pedestal is properly designed and can be served as a heater with thermal control means that is able to precisely maintain the wafer temperature during processes. In general, the heater includes a plate made of ceramic or metal and heating elements sealed in the plate, like heating coils. More specific, the heater may further include other electronic elements such as thermal sensors and a thermal controller.

Said heater plays a key role in many wafer processes (e.g. CVD, PECVE, Optical lithography, etching and cleaning) since the operation of thermal control affects the process of chemical reaction. For example, reaction gas is distributed and deposited onto the reaction surface of the wafer to form a conductive layer or an insulation layer. Said thermal control is a significant approach to obtain a deposition thin film on the wafer with a uniform thickness and fine quality,

A known prior art disclosed in a reference (CN101807515A) is a heater having multiple heating zones, which includes a plate having plural resistive heating elements. Each heating element is configured to produce a particular amount of heat and shaped to fit the corresponding one of the heating zones defined on the plate. The temperature over plate could be maintained to a uniform value by properly controlling the line width and power supply for each of heating elements. In general, heat transfers according to a thermal gradient established in the plate. In the case where the plate includes plural heating elements operated at different levels of heating processes, the complicated heat transfer may become an issue, particularly in a lateral transfer, which will probably affect the required heating duration and the temperature uniformity over the heater.

In view of the background of thermal control as mentioned above, there is a demand in the semiconductor manufacture field to develop a wafer pedestal with multiple heating zones and a preferred heat transferring confinement mechanism.

### SUMMARY

An objective of the present invention is to provide a wafer pedestal including a plate having a top, a bottom opposite to the top and a thickness extending between the top and the bottom, the plate defining a central axis; a heating assembly embedded in the plate; and a thermal insulation assembly embedded in the plate at a radial position, the plate being divided into a first heating zone and a second heating zone based on the radial position.

In one preferred embodiment, the plate has at least one groove extending from the bottom toward the top, the thermal insulation assembly is inserted into the at least one groove.

In one preferred embodiment, the thermal insulation assembly is sealed in the plate.

In one preferred embodiment, the heating assembly includes plural thermal conductive elements extending between the top and the bottom.

In one preferred embodiment, at least a portion of the thermal conductive elements passes through at least a portion of the thermal insulation assembly.

In one preferred embodiment, the thermal insulation assembly has at least one cutout surrounding a portion of the thermal conductive elements.

In one preferred embodiment, the heating assembly includes a first thermal conductive element and a second thermal conductive element extending between the top and the bottom of the plate, wherein the first thermal conductive element is defined by a first radius with respect to the central axis, the second thermal conductive element is defined by a second radius with respect to the central axis, and the thermal insulation assembly is defined by a third radius with respect to the central axis, and wherein the second radius is larger than the third radius that is larger than the first radius.

In one preferred embodiment, the thermal insulation assembly is a ring extending between the top and the bottom of the plate.

In one preferred embodiment, the plate has at least one groove extending from the bottom toward the top, the ring is inserted into the at least one groove.

Another objective of the present invention is to provide a reaction chamber including the wafer pedestal as mentioned above.

The foregoing and other features and advantages of the present disclosure will be described in detail in the following detailed descriptions of several embodiments as well as in the accompanying drawings illustrating the principles of the invention.

### BRIEF DESCRIPTION OF THE DRAWINGS

Aspects of the disclosure can be better understood with reference to the following drawings. Non-limiting and non-exhaustive embodiments are described with reference to the following drawings. The components in the drawings are not necessarily to scale, with the emphasis instead being placed upon illustrating the structure and principles of the invention.

FIG. 1 is a schematic block diagram illustrating a semiconductor reaction chamber using a wafer pedestal in accordance with the invention.

FIG. 2 exemplifies an exterior of the pedestal in accordance with the invention.

FIG. 3 shows an inside configuration of the pedestal in accordance with FIG. 2.

FIG. 4 shows a heating assembly in accordance with FIG. 3

FIG. 5 shows a cross-sectional view of FIG. 3.

FIG. 6 exemplifies another embodiment of the wafer pedestal in accordance with the invention.

FIG. 7 shows the configuration of a heating assembly and a thermal insulation assembly of FIG. 6.

FIG. 8 shows a cross-sectional view of FIG. 6.

### DETAILED DESCRIPTION

The present disclosure will be fully described with reference to the drawings showing illustrated embodiments of the invention. However, given that this claimed subject matter can be achieved through various forms, the construction of the subject matter being covered or filed is not limited to any illustrated embodiments disclosed herein, which are merely illustrative. Similarly, the present disclosure aims to provide a reasonably wide scope to the claimed subject matter being filed or covered. Furthermore, illustrated embodiments of the claimed subject matter can be, for example, a method, a device or a system. Therefore, these embodiments may be implemented in hardware, software, firmware or any form of combination thereof (which is, as it is known, not software).

Appearances of the phrase “in one embodiment” herein are not necessarily referring to the same embodiment, and appearances of the phrase “in other embodiments” herein are not necessarily referring to a different embodiment. This for the purpose of, for example, stating that the claimed subject matter includes combinations of all or part of the illustrated embodiments.

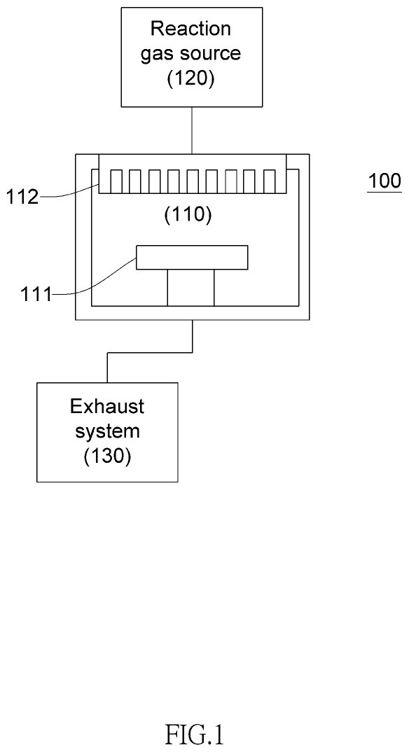

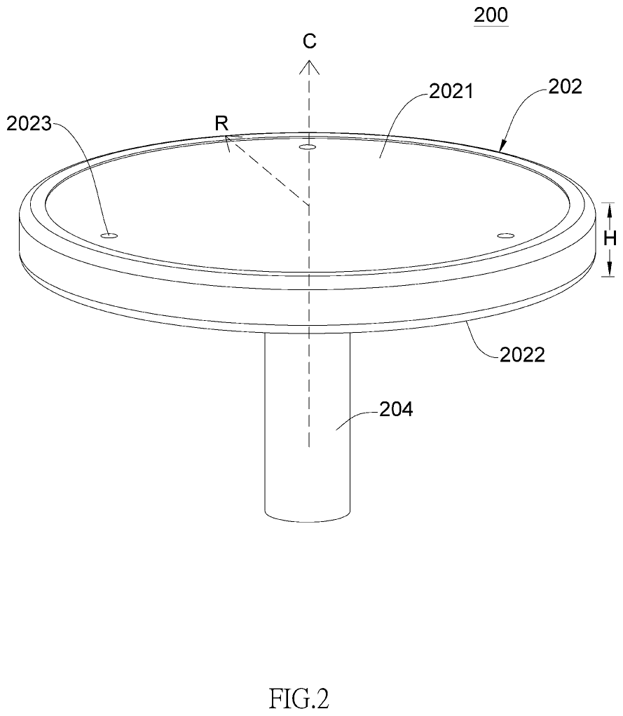

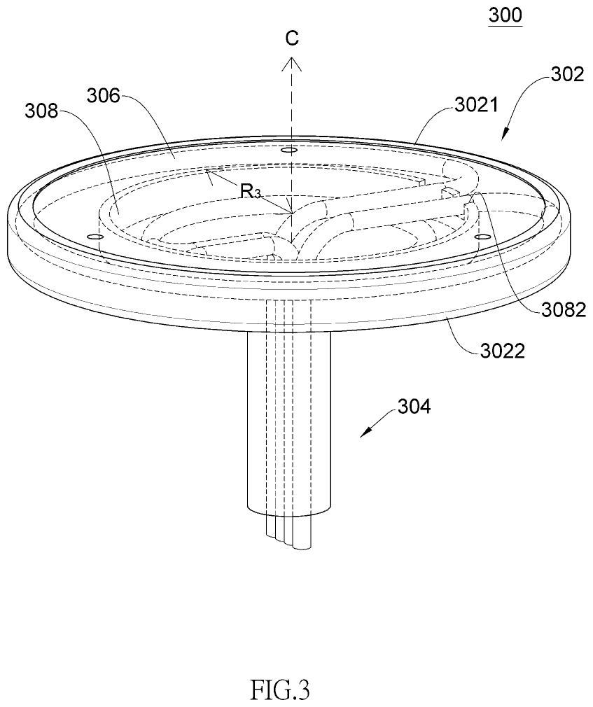

FIG. 1 illustrates an embodiment of a semiconductor processing system (100) which includes a reaction chamber (110), a reaction gas source (120) and an exhaust system (130). The reaction chamber (110) according to the invention (110) mainly includes a wafer pedestal (111) for carrying a wafer, a gas distribution device (112) and at least one exhaust channel (not shown) for removing reacted gases. The reaction chamber (110) is generally a barrel structure. The wafer pedestal (111) has a plate for carrying the wafer and a post for supporting the plate in the chamber as shown in FIG. 2. The plate has a heating assembly embedded therein for heating the wafer as shown in FIG. 3. Generally, the heating assembly is connected to a power source to thereby adjust wafer temperature. Gas distribution device (112) is positioned at the top of the reaction chamber (110) and configured to receive gases from a reaction gas source (120) so that the gases can be released into the chamber (110). Exhaust system (130) has multiple lines, control valves and pumps that work together to control the pressure within the chamber (110). Actually, the system (100) may include more devices and elements or coupled to other systems, which is omitted for brevity.

FIG. 2 illustrates an embodiment of a wafer pedestal (200) according to the invention, which includes a plate (202) and a post (204). The plate (202) has a top (2021), a bottom (2022) opposite to the top (2021) and a thickness (H) extending therebetween. The top (2021) has a lateral carrying surface for carrying a wafer. The bottom (2022) and the post (204) are jointed together or could be integrated as one piece such that the plate (202) can be supported at a position within the chamber.

Despite the absence of a top view in the drawings, the lateral carrying surface of the plate (202) generally is a circular surface. The shape of the top (2021) and/or the bottom (2022) is defined by a central axis (C) and a radius (R) extending radially about the central axis (C). The central axis (C) and the post (204) are substantially parallel, and the central axis (C) is perpendicular to the lateral carrying surface of the top (2021). The radius (R) and the thickness (H) of plate (202) are well determined to define a space sufficient for embedding the heating assembly in the plate (202) as shown in FIG. 3. Based on the arrangement of heating assembly and/or thermal insulation assembly, the plate (202) can be divided into a first heating zone and a second heating zone, or even more, over different radial areas as detailed in the following description.

In the illustrated embodiment, the plate (202) includes plural lift pin guides (2023) extending between the top (2021) and the bottom (2022) to allow corresponding lift pins pass through from the bottom (2022) toward the top (2021) to elevate the wafer. The post (204) extends downward from the bottom (2022) of plate (202). The post (204) is a hollow structure that allow accommodation of parts of the heating assembly, such as metal rods shown in FIG. 3.

FIG. 3 shows a transparent view of an embodiment of the wafer pedestal (300) according to the invention. Similarly, the wafer pedestal (300) includes a plate (302) and a post (304). A portion of a heating assembly (306) and a thermal insulation assembly (308) are embedded into the plate (302). Another portion of the heating assembly (306) extends into the post (304) and electrically couples to a controller (not shown). The heating assembly (306) is properly layout in the plate (302) and generally extend over a lateral area approximately equivalent to the area of said wafer carrying surface. The thermal insulation assembly (308) is positioned in the plate (302) and intersects with the heating assembly (306), which thereby divides the plate (306) into a plurality of lateral heating zones.

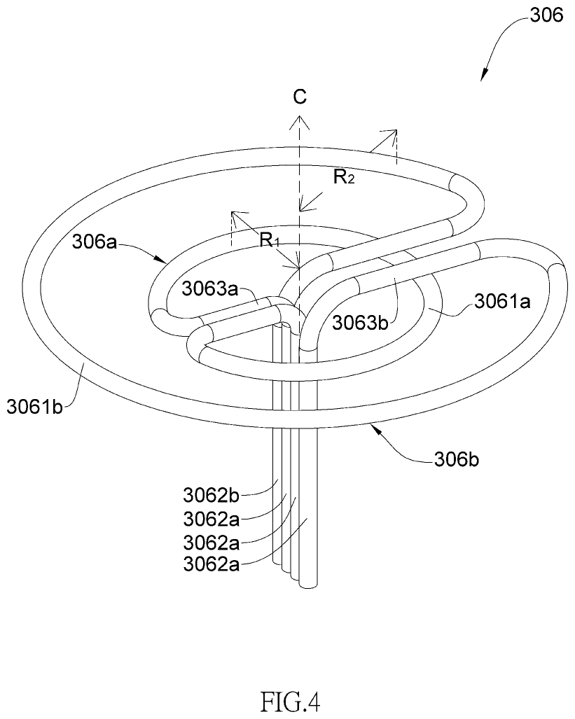

FIG. 4 individually shows the heating assembly (306) of FIG. 3, which includes plural thermal conductive elements (306a, 306b). In one embodiment, each of the thermal conductive elements (306a, 306b), made of a metal, includes a coil member (3061a, 3061b) and an extending member (3062a, 3062b) connected with the coil member (3061a, 3061b). A first thermal conductive element (306a) has a first extending member (3062a) in a vertical direction between the bottom of reaction chamber and the plate. In the embodiment, the first extending member (3062a) is made of two parallel metal rods. The symmetric of first extending member (3062a) can define the central axis (C) of the plate. The first coil member (3061a) of first thermal conductive element (306a) extends over a lateral plane (not depicted) at the top of the first extending member (3062a) and at least in part surrounds the central axis (C) at a first radius (R1). As shown in figure, the first coil member (3061a) is similar with a circular coil. In other embodiments, the shape of first coil member (3061a) may be rectangular, polygon or radiation.

A second thermal conductive element (306b) has a second extending member (3062b) in the vertical direction between the bottom of reaction chamber and the plate. As shown in the figure, the second extending member (3062b) is symmetrical with respect to the central axis (C) and sandwich the first extending member (3062b). The second extending member (3062b) are two parallel metal rods. A second coil member (3061b) of the second thermal conductive element (306b) extends over a lateral plane (not depicted) at the top of the second extending member (3062b) and at least in part surrounds the central axis (C) at a second radius (R2). The second coil member (3061b) is slightly elevated above the first coil member (3061a) to avoid structural interference. The second coil member (3061b) is similar with a circular coil. In other embodiments, the shape of second coil member (3061b) may be rectangular, polygon or radiation.

The first and second coil members (3061a and 3061b) further have initial extending members (3063a, 3063b) provided between the respect extending members (3062a, 3062b) and their coil circumference portions. As shown in figure, a first initial extending member (3063a) and a second initial extending member (3063b) extend in opposite direction from the respective coil portions such that the produced heat will be dispersed over two halves of the plate and avoid heat accumulation on one side. In addition to that, less or more number of thermal conductive elements may be included. For example, the heating assembly may be composed of one single thermal conductive element having plural coil members distributed at different radiuses. Given that, in some embodiments, more heating zones could be defined depending on the number and/or the layout of the coil. In the embodiment, the plate (302) has a first heating zone defined by the first coil member (3061a) and a second heating zone defined by the second coil member (3061b). Said two heating zones might overlap with each other or be separate. In another embodiment, the first coil member (3061a) is elevated slightly higher than the second coil member (3061b). In some embodiments, based on design purpose, said coil member may include portions that extend in vertical direction.

Referring back to FIG. 3, the plate (302) includes the thermal insulation assembly (308) embedded into the plate (302) at a radial position. In the embodiment, the thermal insulation assembly (308) is a ring encircling the central axis (C) and extends a high between the top (3021) and bottom (3022) of the plate. As shown in the figure, the thermal insulation assembly (308) is positioned among and intersects with the heating assembly (306). Said intersection is that an extension direction of a portion of the thermal insulation assembly is different from an extension direction of a portion of the heating assembly (306), and a portion of the heating assembly (306) passes through the thermal insulation assembly (308). Alternatively, portions of the thermal insulation assembly (308) are arranged between the thermal conductive elements. A vertical high of the thermal insulation assembly (308) covers a vertical extension of the heating assembly (306) to reach a certain extent of heat insulation. As shown in the figure, the vertical extension of the thermal insulation assembly (308), i.e. the ring, is larger than the distance between the first coil member (3061a) and the second coil member (3061b) of the heating assembly (306). Thereby, the thermal insulation assembly (308) can restrict the lateral heat transfer from one coil member to another in order to sustain heat in a certain heating zones.

As shown in the figure, a portion of the thermal insulation assembly (308) according to the embodiment has one or more cutouts (3082) formed thereon that respectively corresponds to the initial extending member (3063b) of the second coil member (3061b) such that a portion of the second coil member (3061b) passes through and surrounds the insulation structure. Among the various changes, the shape and position of cutouts may be determined depending on the layout of thermal conductive elements. In the embodiment, the thermal insulation assembly (308) is positioned at a third radius (R3) with respect to the central axis (C). As can be seen in FIGS. 3 and 4, the second radius (R2) is larger than the third radius (R3) that is larger than the first radius (R1). Therefore, the thermal insulation assembly (308) according to the embodiment divides the plate (302) into a first heating zone and a second heating zone. The first heating zone is defined by an area bounded by the third radius (R3) about the central axis (C) and the second heating zone is defined by an area bounded by the third radius (R3) and plate the circumference. Alternatively, the plate (302) can be divided into more heating zones. For example, a first heating zone can be defined by the first radius (R1) about the central axis (C), a second heating zone can be defined by the first radius (R1) and the third radius (R3), a third heating zone can be defined by the third radius (R3) and the second radius (R2), and so on. Thus, the plate of wafer pedestal according to the invention may be operative to provide means for multi-zone heating to achieve thermal gradient control. In some possible embodiments, said thermal insulation assembly may not be an integration structure. Instead, plural thermal insulation units may be embedded into the plate at one or more radial positions to restrict lateral thermal transfer. For example, in other embodiments, more independent insulation units or members could be deployed at the radial positions between the central axis (C) and the plate circumference. In some embodiments, more independent insulation units or members could be positioned in a vertical direction between the top and bottom of the plate.

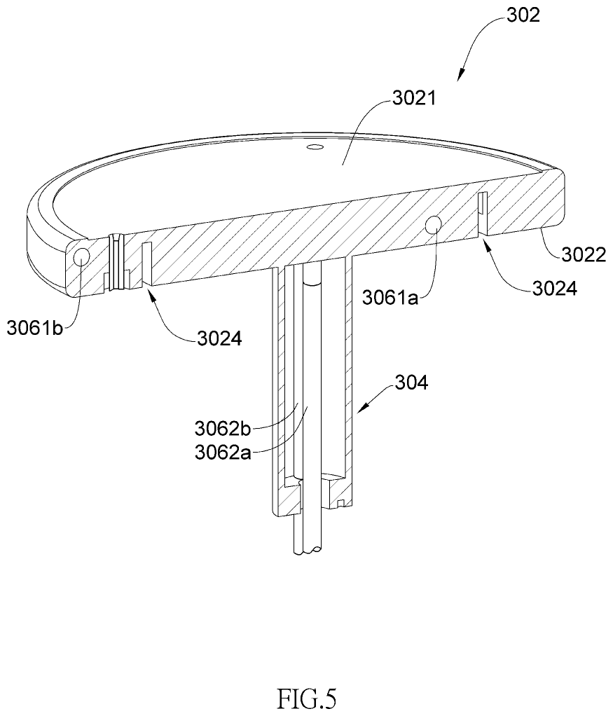

FIG. 5 shows a cross-sectional view according to FIG. 3. In one embodiment, the bottom (3022) of plate (302) has at least one groove (3024), e.g. a circular groove extending from the bottom (3022) to the top (3021) into which the thermal insulation assembly (308) in FIG. 3 could be correspondingly inserted, such as a ring of insulation material. Using known method, the thermal insulation assembly may be firmly inserted within or removed from the groove. In one embodiment, said thermal insulation assembly may be a structure forged by stainless steel.

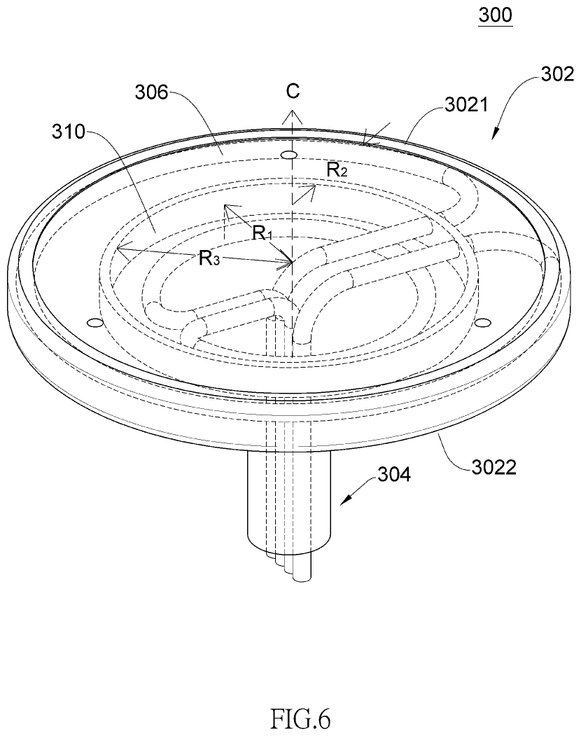

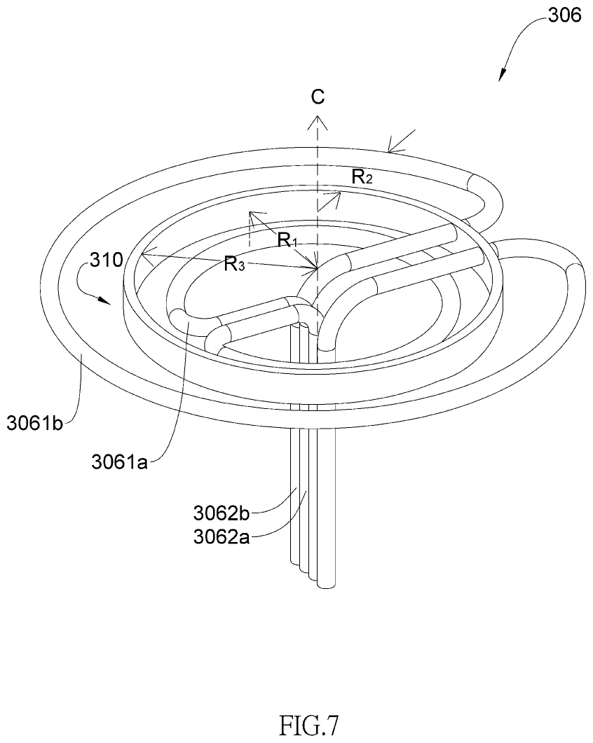

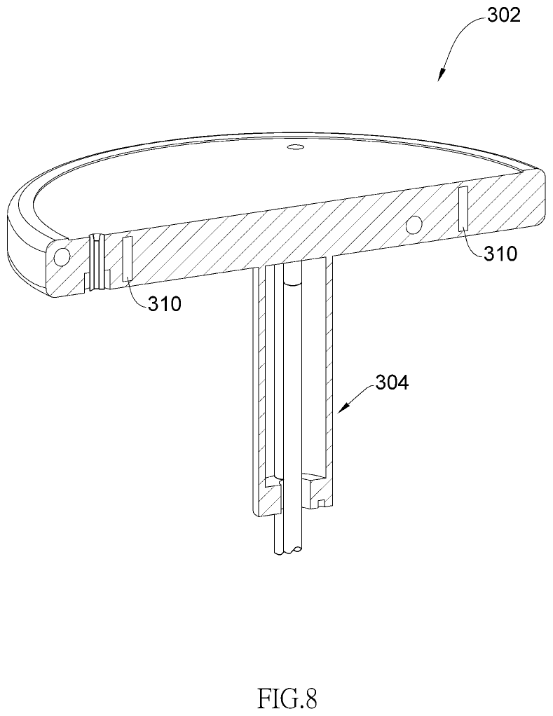

FIG. 6 illustrates another embodiment of the wafer pedestal according to the invention. FIG. 7 individually shows a heating assembly (306) in FIG. 6 and a thermal insulation assembly (310) arranged therein. In comparison with foregoing embodiment, the thermal insulation assembly (310) does not have the cutouts (3082) as shown in FIG. 3, instead a portion of the heating assembly is allowed to passes through the ring directly. With cancellation of cutout design, the ring may possess extra vertical extension. Otherwise, in the case where the ring has cutouts, the produced heat may easily transfer through the cutouts between the inside and outside coil members. FIG. 8 shows a cross-sectional view according to FIG. 6. In comparison with the foregoing embodiment, the thermal insulation assembly (310) depicted herein is fully embedded in the plate (302) which can be done by known methods.

The wafer pedestal according to the invention provides a plate with heating means. Particularly, the plate includes a heating assembly and a thermal insulation assembly embedded therein. Said thermal insulation assembly is embedded within the plate according to one or more radial positions and extends in a vertical direction in order to cover the most of a longitudinal area of the plate. Based on said radial positions and the insulation layout, the plate can be at least divided into a first heating zone and a second zone to thereby fulfill a multi-zone heating approach for wafer while the thermal gradient of the wafer can be controlled.

Although certain details have been used to describe the present disclosure for a better understanding, it will be appreciated that certain changes and modifications may be made thereto within the scope of the claims. Therefore, the foregoing embodiments are presented merely as an exemplary and are not intended to limit the present disclosure. Also, the present disclosure is not limited by the details in the description herein, but allows to be modified within the scope of the appended claims and their equivalents.

What is claimed is:

1. A wafer pedestal, comprising:
a plate having a top, a bottom opposite to the top and a thickness extending between the top and the bottom, the plate defining a central axis;
a heating assembly embedded in the plate; and
a thermal insulation assembly embedded in the plate at a radial position, the plate being divided into a first heating zone and a second heating zone based on the radial position.

2. The wafer pedestal as claimed in claim 1, wherein the plate has at least one groove extending from the bottom toward the top, the thermal insulation assembly is inserted into the at least one groove.

3. The wafer pedestal as claimed in claim 1, wherein the thermal insulation assembly is sealed in the plate.

4. The wafer pedestal as claimed in claim 1, wherein the heating assembly includes plural thermal conductive elements extending between the top and the bottom.

5. The wafer pedestal as claimed in claim 4, wherein at least a portion of the thermal conductive elements passes through at least a portion of the thermal insulation assembly.

6. The wafer pedestal as claimed in claim 4, wherein the thermal insulation assembly has at least one cutout surrounding a portion of the thermal conductive elements.

7. The wafer pedestal as claimed in claim 1, wherein the heating assembly includes a first thermal conductive element and a second thermal conductive element extending between the top and the bottom of the plate, wherein the first thermal conductive element is defined by a first radius with respect to the central axis, the second thermal conductive element is defined by a second radius with respect to the central axis, and the thermal insulation assembly is defined by a third radius with respect to the central axis, and wherein the second radius is larger than the third radius that is larger than the first radius.

8. The wafer pedestal as claimed in claim 1, wherein the thermal insulation assembly is a ring extending between the top and the bottom of the plate.

9. The wafer pedestal as claimed in claim 8, wherein the plate has at least one groove extending from the bottom toward the top, the ring is inserted into the at least one groove.

10. A reaction chamber, comprising:
a wafer pedestal, comprising:
a plate having a top, a bottom opposite to the top and a thickness extending between the top and the bottom, the plate defining a central axis;
a heating assembly embedded in the plate; and
a thermal insulation assembly embedded in the plate at a radial position, the plate being divided into a first heating zone and a second heating zone based the radial position.
